(19) United States
(12) Patent Application Publication
(10) Pub. No.: US 2018/0062079 A1
(43) Pub. Date: Mar. 1, 2018

(54) DEPOSITION MASK ASSEMBLY

(71) Applicant: SAMSUNG DISPLAY CO., LTD., Yongin-si (KR)

(72) Inventors: Junhyeuk KO, Yongin-si (KR); Seungjin LEE, Suwon-si (KR)

(21) Appl. No.: 15/623,520

(22) Filed: Jun. 15, 2017

(30) Foreign Application Priority Data
Aug. 24, 2016 (KR) 10-2016-0107666

(51) Int. Cl. H01L 51/00; H01L 27/32; C23C 14/04; C23C 14/12; H01L 51/56

(52) U.S. Cl. CPC H01L 51/0011; H01L 27/3258; H01L 51/001; H01L 2227/323; C23C 14/12; H01L 51/56; C23C 14/042

(57) ABSTRACT

A deposition mask assembly including: a frame, a pair of auxiliary masks and a deposition divided mask. The frame includes an opening area through which deposition material passes, and first, second, third and fourth side portions which collectively define the opening area. The pair of auxiliary masks are on the frame, fixed to the first and third side portions which face each other in a first direction with respect to the opening area thereof, and disposed respectively adjacent to the second and fourth side portions which face each other in a second direction crossing the first direction. The divided mask is spaced apart from each of the pair of auxiliary masks and fixed to the first and third side portions. In the second direction, a width of the pair of auxiliary masks is less than a width of the divided mask.

This application claims priority to Korean Patent Application No. 10-2016-0107666, filed on Aug. 24, 2016, and all the benefits accruing therefrom under 35 U.S.C. §119, the content of which in its entirety is herein incorporated by reference.

### BACKGROUND

### 1. Field

Exemplary embodiments of the invention relate to a deposition mask assembly.

### 2. Description of the Related Art

Display devices are classified into a liquid crystal display (“LCD”) device, an organic light emitting diode (“OLED”) display device, a plasma display panel (“PDP”) device, an electrophoretic display (“EPD”) device, and the like, based on a light emitting scheme thereof.

Among the types of the display devices, OLED display devices, having excellent display properties in terms of a contrast ratio and a response time, are advantageous for forming a flexible display device and thus have drawn attention as a display device of the next generation.

An OLED display device typically has a multilayer organic thin film structure, on a substrate, which includes organic materials and is covered by an anode and a cathode. When a voltage is applied to the anode and the cathode, electrical current may flow such that the OLED display device may emit light from the organic thin film structure. That is, in a case where organic molecules are transitioned to have an excited state by the electrical current inflow and then fall into an initial ground state, excessive energy is emitted in the form of light. In order to form such an OLED display device including multilayer organic thin films, it is necessary that each of the organic thin films is deposited to have a uniform thickness across a substrate.

### SUMMARY

Exemplary embodiments of the invention are directed to a deposition mask assembly that may improve precision and uniformity of deposition on a target substrate by effectively reducing bending or sagging of a deposition mask.

According to an exemplary embodiment of the invention, a deposition mask assembly includes: a frame, a pair of auxiliary masks and a deposition divided mask. The frame includes an opening area through which deposition material passes, and first, second, third and fourth side portions which collectively define the opening area. The pair of auxiliary masks are on the frame, fixed to the first and third side portions which face each other in a first direction with respect to the opening area thereof, and disposed respectively adjacent to the second and fourth side portions which face each other in a second direction crossing the first direction. The divided mask is spaced apart from each of the pair of auxiliary masks and fixed to the first and third side portions. In the second direction, a width of the pair of auxiliary masks is less than a width of the divided mask.

The pair of auxiliary masks may not overlap the second side portion and the fourth side portion of the frame.

The width of the pair of auxiliary masks may be in a range of about 3 millimeters (mm) to about 20 mm.

A thickness of the pair of auxiliary masks may be less than a thickness of the divided mask.

A thickness of each of the pair of auxiliary masks may be in a range of about 5 micrometers (μm) to about 20 μm.

The pair of auxiliary masks may include substantially a same material as a material included in the divided mask.

The pair of auxiliary masks may include an invar alloy.

The pair of auxiliary masks may be weld-fixed to the first side portion and the third side portion.

The frame further may include a supporting member disposed across the opening area.

The supporting member and the frame may be unitary.

The foregoing is illustrative only and is not intended to be in any way limiting. In addition to the illustrative embodiments, and features described above, further embodiments, and features will become apparent by reference to the drawings and the following detailed description.

### BRIEF DESCRIPTION OF THE DRAWINGS

The above and other features of the present disclosure of invention will be more clearly understood from the following detailed description taken in conjunction with the accompanying drawings, in which:

FIG. 1 is an exploded perspective view illustrating an exemplary embodiment of a deposition mask assembly;

FIG. 2 is a top plan view illustrating an exemplary embodiment of a deposition mask assembly;

FIG. 3 is a cross-sectional view taken along line I-I′ of FIG. 2;

FIG. 4 is a top plan view illustrating an alternative exemplary embodiment of a deposition mask assembly;

FIG. 5 is a cross-sectional view taken along line II-IP of FIG. 4;

FIG. 6 is a cross-sectional view illustrating a deposition process of a display device using an exemplary embodiment of a deposition mask assembly; and

FIG. 7 is a cross-sectional view illustrating an organic light emitting diode (“OLED”) display device manufactured using an exemplary embodiment of a deposition mask assembly.

### DETAILED DESCRIPTION

Exemplary embodiments will now be described more fully hereinafter with reference to the accompanying drawings. Although the invention can be modified in various manners and have several embodiments, exemplary embodiments are illustrated in the accompanying drawings and will be mainly described in the specification. However, the scope of the invention is not limited to the exemplary embodiments and should be construed as including all the changes, equivalents, and substitutions included in the spirit and scope of the invention.

In the drawings, thicknesses of a plurality of layers and areas are illustrated in an enlarged manner for clarity and ease of description thereof. When a layer, area, or plate is referred to as being related to another element such as being “on” another layer, area, or plate, it may be directly on the other layer, area, or plate, or intervening layers, areas, or plates may be present therebetween. Conversely, when a layer, area, or plate is referred to as being related to another element such as being “directly on” another layer, area, or plate, intervening layers, areas, or plates may be absent therebetween. Further when a layer, area, or plate is referred to as being related to another element such as being “below” another layer, area, or plate, it may be directly below the other layer, area, or plate, or intervening layers, areas, or plates may be present therebetween. Conversely, when a layer, area, or plate is referred to as being related to another element such as being “directly below” another layer, area, or plate, intervening layers, areas, or plates may be absent therebetween.

The spatially relative terms “below,” “beneath,” “less,” “above,” “upper” and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “physically connected” to the other element, or “electrically connected” to the other element with one or more intervening elements interposed therebetween.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Some of the parts which are not associated with the description may not be provided in order to specifically describe embodiments of the present invention, and like reference numerals refer to like elements throughout the specification.

In a method of manufacturing an organic light emitting diode (“OLED”) display device including a multilayer organic thin film structure on a substrate, organic thin films may be formed through a deposition process using a deposition mask. In general, in forming a deposition mask assembly, the deposition mask is fixed to a frame having an opening area, to maintain a strength of the deposition mask and the deposition mask assembly. In such an example, as the size of a substrate to be subject to deposition increases, the deposition mask having a corresponding increasing size may undesirably experience sagging.

In addition, in order to closely contact the deposition mask assembly and the subject substrate to each other, a magnetic force between a magnet unit and the deposition mask assembly is utilized. In such an example, the magnetic force may affect a side portion of a mask pattern adjacent to the frame of the deposition mask assembly, such that a magnet edge phenomenon may occur whereby the deposition pattern formed on the substrate by using the deposition mask is distorted. Accordingly, deposition precision may be undesirably degraded.

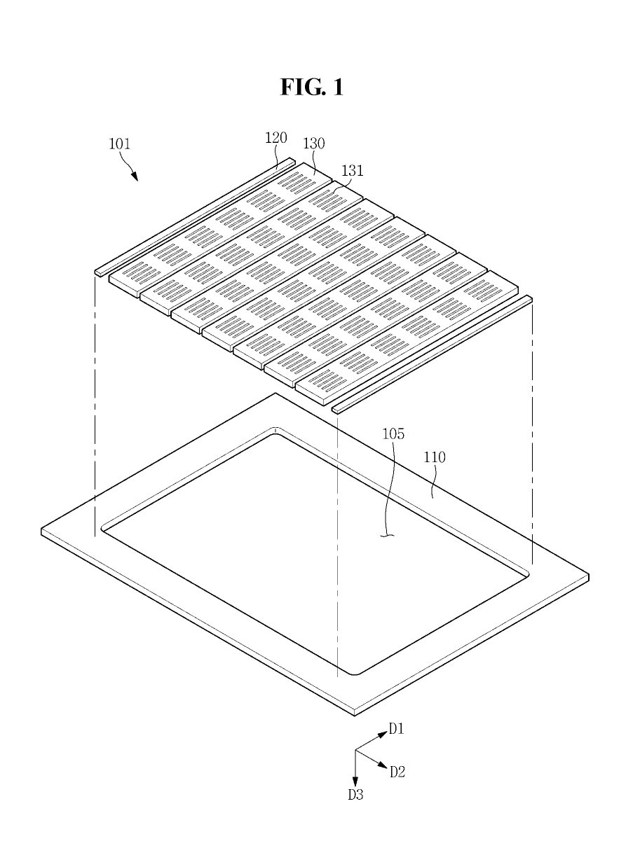

Hereinafter, an exemplary embodiment of a deposition mask assembly will be described with reference to FIGS. 1, 2 and 3.

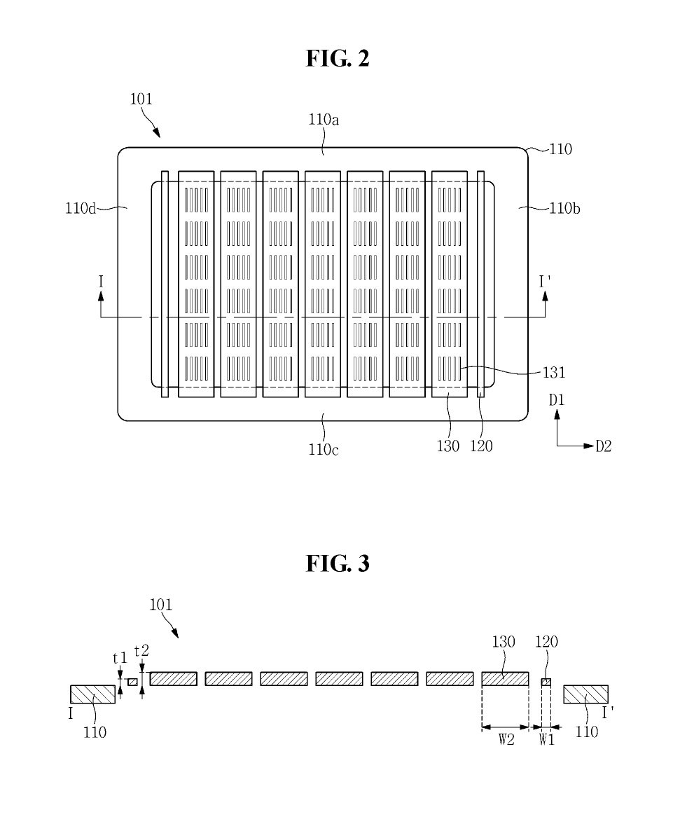

FIG. 1 is an exploded perspective view illustrating an exemplary embodiment of a deposition mask assembly 101, FIG. 2 is a top plan view illustrating an exemplary embodiment of the deposition mask assembly 101, and FIG. 3 is a cross-sectional view taken along line I-I′ of FIG. 2.

Referring to FIGS. 1 and 2, an exemplary embodiment of the deposition mask assembly 101 includes a frame 110, an auxiliary mask 120 provided in plurality to define a pair of auxiliary masks 120, and a divided mask 130 provided in plurality to define a plurality of divided masks 130. Only one pair of auxiliary masks 120 may be provided, but the invention is not limited thereto. Hereinbelow, for ease of description, a relatively short side direction of the frame 110 is defined as lengthwise extending a first direction D1, a relatively long side direction of the frame 110 is defined as lengthwise extending in a second direction D2 which crosses the first direction D1, and a thickness (e.g., cross-sectional) direction of the frame 110 is defined as a third direction D3 which crosses both the first and second directions D1 and D2. The frame 110 and collection of masks 120 and 130 may each be disposed in a plane parallel to a plane defined by the first and second directions D1 and D2.

The frame 110 includes or defines an opening area 105 in a central portion thereof, and includes first, second, third and fourth side portions 110a, 110b, 110c and 110d that collectively define the opening area 105. The frame 110 may include a single one opening defined by the first, second, third and fourth side portions 110a, 110b, 110c and 110d, but the invention is not limited thereto. As illustrated in FIGS. 1 and 2, for example, the frame 110 may have an overall quadrangular shape in the top plan view and may correspond to a substrate that is to be subject to deposition. The frame 110 may include or define the opening area 105, having a quadrangular shape, in the central portion thereof so that a deposition process may be performed on the subject substrate at or through the opening area 105.

The first, second, third and fourth side portions 110a, 110b, 110c and 110d are connected to one another to form the frame 110 having a quadrangular shape. Among the side portions surrounding the opening area 105, the first side portion 110a overlaps a first end portion of each of the pair of auxiliary masks 120 and a first end portion of each of the plurality of divided masks 130. The second side portion 110b is connected to the first side portion 110a, among the side portions surrounding the opening area 105, not overlapping the pair of auxiliary masks 120 and the plurality of divided masks 130. The third side portion 110c faces the first side portion 110a, among the side portions surrounding the opening area 105, and overlaps a second end portion of each of the pair of auxiliary masks 120 opposite to the first ends thereof and a second end portion of the plurality of divided masks 130 opposite to the first ends thereof. The fourth side portion 110d faces the second side portion 110b, among the side portions surrounding the opening area 105, not overlapping the pair of auxiliary masks 120 and the plurality of divided masks 130.

The pair of auxiliary masks 120 and the plurality of divided masks 130 are disposed on the frame 110 to be spaced apart from one another in the second direction D2. In such an exemplary embodiment, the pair of auxiliary masks 120 and the plurality of divided masks 130 are fixed to the frame 110 while receiving a tensile force in the first direction D1. Accordingly, the frame 110 may receive a compressive force, in the first direction D1, which is a reaction to the tensile force of the pair of auxiliary masks 120 and the plurality of divided masks 130 fixed to the frame 110. In addition, when the pair of auxiliary masks 120 and the plurality of divided masks 130 are attached (e.g., welded) to the frame 110 to be fixed thereto, the frame 110 may experience deformation due to heat. Accordingly, the frame 110 may include a metal having relatively high rigidity in order to significantly reduce deformation thereof due to the compressive force or heat exerted to the frame 110.

The pair of auxiliary masks 120 are disposed at opposite sides of the opening area 105 to be disposed above the opening area 105 in the third direction D3. In an exemplary embodiment, for example, the pair of auxiliary masks 120 are disposed between the second and fourth side portions 110b and 110d of the frame 110, while not overlapping the second and fourth side portions 110b and 110d to be spaced apart therefrom. Opposite (first and second) end portions of each of the auxiliary masks 120 overlap the first and third side portions 110a and 110c, respectively, which face each other, and are welded to the first and third side portions 110a and 110c, respectively.

The pair of auxiliary masks 120 may include at least one selected from: stainless steel (“SUS”), an invar alloy, nickel (Ni), cobalt (Co), a nickel alloy and a nickel-cobalt alloy.

The plurality of divided masks 130 are disposed among the pair of auxiliary masks 120. That is, the plurality of divided masks 130 are collectively disposed between the pair of auxiliary masks 120 and are arranged continuously along the second direction D2, not overlapping the pair of auxiliary masks 120 to be spaced apart therefrom. Opposite (first and second) end portions of each of the divided masks 130 overlap the first and third side portions 110a and 110c, respectively, which face each other, and are welded to the first and third side portions 110a and 110c, respectively.

The plurality of divided masks 130 may include at least one selected from: stainless steel (“SUS”), an invar alloy, nickel (Ni), cobalt (Co), a nickel alloy and a nickel-cobalt alloy.

Each of the plurality of divided masks 130 includes a deposition pattern 131 at a portion thereof overlapping the opening area 105. Deposition material may pass through the divided mask 130 at the deposition pattern 131. The deposition pattern 131 may have a plurality of slits. The slit may completely pass through the divided mask 130 along the third direction D3 which is a thickness direction of the divided mask 130. In an alternative exemplary embodiment, only a portion of the divided mask 130 may be etched such that the slit may not completely pass through the divided mask 130. The slit may be modified into various shapes, e.g., a strip shape or a dot shape, based on a pattern of an organic thin film to be deposited in the display device.

The deposition pattern 131 may be provided in plurality along a length direction (e.g., first direction D1) of a single divided mask 130. The plurality of deposition patterns 131 may be spaced apart from each other by a non-deposition portion of the divided mask 130. The non-deposition portion may be a solid portion (e.g., non-slit or non-opening) of the divided mask 130. The auxiliary mask 120 may include only a solid portion, but the invention is not limited thereto. As including the deposition pattern 131, the divided mask 130 may be otherwise referred to as a deposition mask of the deposition mask assembly 101. The auxiliary mask 120 may be otherwise referred to as a non-deposition mask of the deposition mask assembly 101 since a deposition material may not be passed through the auxiliary mask 120.

By including the plurality of divided masks 130 corresponding to the opening area 105 rather than a single mask that has an overall size corresponding to that of the opening area 105, an exemplary embodiment of the deposition mask assembly 101 may reduce or effectively prevent mask deformation that may occur due to heat generated in a deposition process and may reduce sagging of the mask.

As described hereinabove, in an exemplary embodiment, the pair of auxiliary masks 120 and the plurality of divided masks 130 are welded to the frame 110 to be fixed thereto.

As illustrated in FIGS. 1 and 2, for example, the pair of auxiliary masks 120 and the plurality of divided masks 130 are each lengthwise disposed to cross the opening area 105 along the first direction D1, and opposite end portions of each of the pair of auxiliary masks 120 and the plurality of divided masks 130 are welded to the first and third side portions 110a and 110c of the frame 110, respectively. The attachment of the pair of auxiliary masks 120 and the plurality of divided masks 130 may be provided at non-deposition (e.g., solid portions thereof) at areas of the frame overlapped thereby. In such an exemplary embodiment, welding may employ spot welding. The spot welding is a method whereby a plurality of discrete welding points are determined and each of the plurality of welding points are welded such that deformation of the divided mask 130 may be significantly reduced in the welding process. The welding points may form, e.g., at least one column or a zigzag shape.

As such, by including the pair of auxiliary masks 120 that are adjacent to outermost divided masks 130 in the second direction D2 and do not overlap the second and fourth side portions 110b and 110d, an exemplary embodiment of the deposition mask assembly 101 may prevent or significantly reduce deformation of the outermost divided masks 130 or distortion of the deposition pattern 131 that may occur due to a magnetic force transmitted through the frame 110. Accordingly, degradation of deposition precision and deposition uniformity of the organic thin film may be prevented, and life span and reliability of the display device may be improved.

Referring to FIG. 3, in an exemplary embodiment, the pair of auxiliary masks 120 may have a less width in the second direction D2 and a less thickness in the third direction D3 than those of the plurality of divided masks 130.

In a case where a width of a single auxiliary mask 120 is defined as a first width W1 and a width of a single divided mask 130 is defined as a second width W2, the first width W1 is less than the second width W2. In an exemplary embodiment, for example, the second width W2 may be about two times to about thirty times the first width W1, and in such an exemplary embodiment, the first width W1 may be in a range of about 3 millimeters (mm) to about 20 mm. Accordingly, the pair of auxiliary masks 120 may occupy relatively less space in the top plan view, and may reduce or effectively prevent deformation of the outermost divided masks 130 and distortion of the deposition pattern 131 thereof that may occur due to the magnetic force.

In addition, in a case where a thickness of a single auxiliary mask 120 is defined as a first thickness t1 and a thickness of a single divided mask 130 is defined as a second thickness t2, the first thickness t1 is less than the second thickness t2. In an exemplary embodiment, for example, the second thickness t2 may be about 1.5 times to about 2.5 times the first thickness t1, and in such an exemplary embodiment, the first thickness t1 may be in a range of about 5 micrometers (μm) to about 20 μm.

In an exemplary embodiment, a single auxiliary mask 120 is described as having a less thickness than a thickness of a single divided mask 130, but exemplary embodiments are not limited thereto. In an alternative exemplary embodiment, a single auxiliary mask 120 may have substantially a same thickness as that of a single divided mask 130. Thus, as having the same thickness as that of a single divided mask 130, providing the auxiliary mask 120 having a less width may be easier.

The pair of auxiliary masks 120 and the plurality of divided masks 130 may each include substantially a same material. In an exemplary embodiment, for example, the pair of auxiliary masks 120 and the plurality of divided masks 130 may include an invar alloy. By including the pair of auxiliary masks 120 and the plurality of divided masks 130 that include substantially a same invar alloy, an exemplary embodiment of the deposition mask assembly 101 may reduce or effectively prevent deformation of the outermost divided mask 130 and distortion of the deposition pattern 131 that may occur due to the magnetic force.

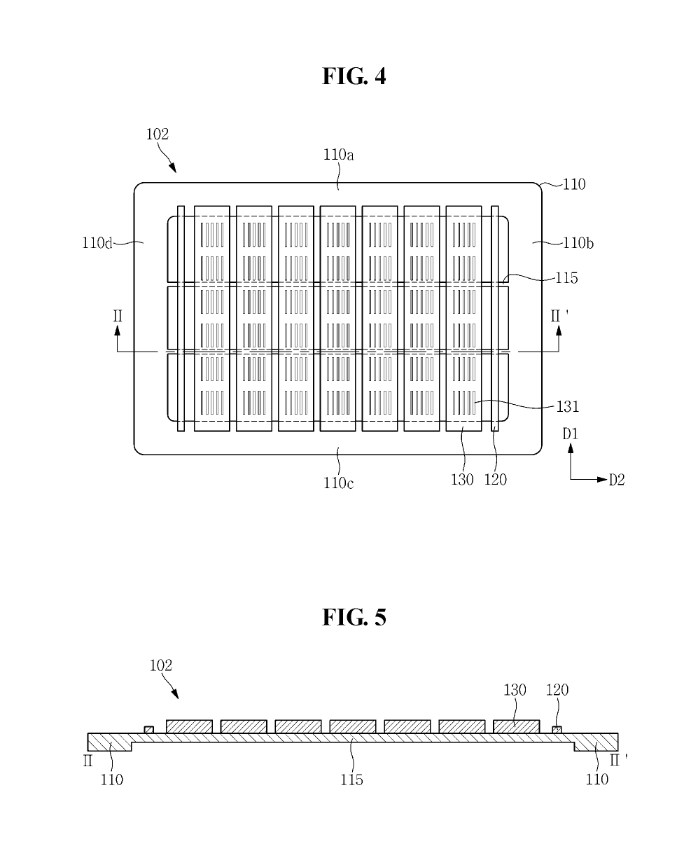

Hereinbelow, an alternative exemplary embodiment of a deposition mask assembly will be described with reference to FIGS. 4 and 5.

FIG. 4 is a top plan view illustrating an alternative exemplary embodiment of a deposition mask assembly, and FIG. 5 is a cross-sectional view taken along line II-IP of FIG. 4.

Referring to FIGS. 4 and 5, an alternative exemplary embodiment of a deposition mask assembly 102 further includes a supporting member 115 across the opening area 105 defined by first, second, third and fourth side portions 110a, 110b, 110c and 110d of a frame 110 according to an exemplary embodiment.

The supporting member 115 may be provided in plurality across the opening area 105 of the frame 110 to define a collective supporting member 115. The collective supporting member 115 may divide the opening area 105 into a plurality of opening sub-areas through which a deposition process may be performed on a subject substrate.

The supporting member 115 is disposed across the opening area 105 (refer to FIG. 2) to be fixed to second and fourth side portions 110b and 110d of the frame 110. That is, the supporting member 115 is lengthwise disposed along a second direction D2, parallel to first and third side portions 110a and 110c of the frame 110. In a cross-sectional direction, a total thickness or height of the supporting member 115 may be less than or equal to a total thickness or height of remaining portions of the frame 110 such as including the first, second, third, and fourth side portions 110a, 110b, 110c, and 110d. In addition, although not illustrated, a collective supporting member including the supporting member 115 may further include a supporting member lengthwise disposed along a first direction D1 which is a length direction of a divided mask 130, based on the size of the frame 110.

The collective supporting member 115 and the frame 110 may be unitary, including substantially a same material. Accordingly, the collective supporting member 115, similar to the frame 110, may include a metal having high rigidity, thus not easily deformed by a compressive force or heat.

A width of the supporting member 115 in the first direction D1 is defined crossing the length thereof in the second direction D2. The width of the supporting member 115 in the first direction D1 may be greater than or equal to a gap between adjacent divided masks 130 in the second direction D2. In an exemplary embodiment, however, the width of the supporting member 115 may be in a range not to overlap a deposition pattern 131 of the divided mask 130.

By further including the supporting member 115 disposed across the opening area 105, an alternative exemplary embodiment of the deposition mask assembly 101 may reduce or effectively prevent sagging of the divided mask 130. Accordingly, degradation of deposition precision and deposition uniformity of organic thin films may be reduced or effectively prevented, and life span and reliability of the display device may be improved.

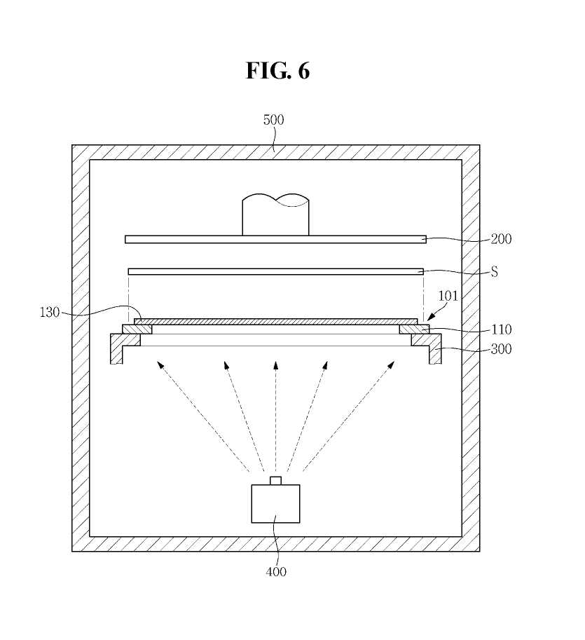

Hereinafter, a deposition process of a display device using an exemplary embodiment of a deposition mask assembly will be described with reference to FIG. 6.

FIG. 6 is a cross-sectional view illustrating a deposition process of a display device using an exemplary embodiment of a deposition mask assembly.

Referring to FIG. 6, an exemplary embodiment of a deposition processing apparatus includes a deposition mask assembly 101, a magnet unit 200, a fixing member 300, an evaporation source 400 and a chamber 500. The deposition mask assembly 101, the magnet unit 200, the fixing member 300 and the evaporation source 400 may be disposed in the chamber 500.

The deposition mask assembly 101 includes a frame 110, an auxiliary mask 120 and a divided mask 130, and is disposed at an inner and upper portion of the chamber 500 to face the evaporation source 400.

The magnet unit 200 opposes the deposition mask assembly 101, having a substrate S to be subject to deposition, therebetween. Due to a magnetic force exerted by the magnet unit 200, the divided mask 130 of the deposition mask assembly 101 may closely contact the substrate S.

The fixing member 300 supports an edge portion of the deposition mask assembly 101. The fixing member 300 may define a passage through which an organic material supplied from the evaporation source 400 moves to the substrate S. End portions of the fixing member 300 are disposed outwardly from the passage through which the organic material supplied from the evaporation source 400 moves to the substrate S.

The evaporation source 400 is disposed below the deposition mask assembly 101, and supplies the organic material to the substrate S through a deposition pattern 131 of the divided mask 130. That is, the organic material is supplied to a deposition surface of the substrate S at an inner and upper portion of the chamber 500.

The evaporation source 400 may be in a form of a heating crucible that accommodates an organic material thereinside, and may evaporate, using heat, the organic material to be deposited on the substrate S. The deposition processing apparatus may further include a heater (not illustrated) to heat the organic material. The heaters are disposed on opposite sides of the evaporation source 400, and serve to heat the evaporation source 400 so that the organic material accommodated in the evaporation source 400 sublimates.

The chamber 500 provides a space in which the deposition process to be performed and in which members of the deposition apparatus are disposed. The chamber 500 is connected to a vacuum pump (not illustrated) such as a turbo molecular pump (“TMP”) to maintain inside of the chamber 500 in a vacuum state. The chamber 500 may further include a deposition prevention plate (not illustrated) covering an inner wall surface of the chamber 500. The deposition prevention plate prevents an organic material that is not deposited on the substrate S, among the organic material discharged from the evaporation source 400, from adhering to the inner wall surface of the chamber 500.

The substrate S is disposed above the deposition mask assembly 101. The substrate S may be disposed to overlap the opening area 105 of the deposition mask assembly 101. In addition, the substrate S may be a predetermined distance spaced apart from an upper portion of the deposition mask assembly 101.

Although not illustrated, the deposition processing apparatus may further include a thickness monitoring sensor for measuring the speed of the organic material that is evaporated, a thickness controller for controlling the evaporation source 400 based on the measured thickness and/or a shutter for blocking the organic material evaporated from the evaporation source 400, for example. In addition, in order to align the substrate S and the deposition mask assembly 101, the deposition processing apparatus may further include an aligner, and a charge-coupled device (“CCD”) camera on the outside of the chamber 500.

A process whereby the deposition material is deposited on the deposition surface of the substrate S will be briefly described hereinbelow.

The deposition mask assembly 101 is fixed to the fixing member 300, and the substrate S is disposed above the divided mask 130 of the fixed deposition mask assembly 101.

Subsequently, the evaporation source 400 at an inner and lower portion of the chamber 500 discharges an organic material toward the deposition mask assembly 101. In an exemplary embodiment, for example, when a power is applied to a heater connected to the evaporation source 400, the evaporation source 400 in which the organic material is accommodated is heated. Accordingly, the organic material is heated and sublimates to be discharged toward the deposition mask assembly 101. In such an exemplary embodiment, an inside of the chamber 500 may be maintained at a relatively high degree of vacuum state and relatively high temperature.

When discharged, the organic material is deposited on the deposition surface of the substrate S through the deposition pattern 131 of the divided mask 130. Such deposition may form one or more thin film. By repeating the aforementioned process, multilayer organic thin films may be formed on the substrate S.

As an overall planar size of display devices increases, the size of vacuum deposition apparatuses increases and the size of the deposition mask assembly 101 including a deposition mask also increases. Accordingly, the deposition mask may experience bending and sagging to a great extent. One or more exemplary embodiment of the deposition mask assembly of the invention may effectively reduce the bending and sagging phenomenon, thus capable of reducing or effectively preventing an issue of degradation in deposition precision and deposition uniformity of organic films on the substrate S. Accordingly, life span and reliability of display devices formed through a deposition process using one or more exemplary embodiment of the deposition mask assembly of the invention may be improved.

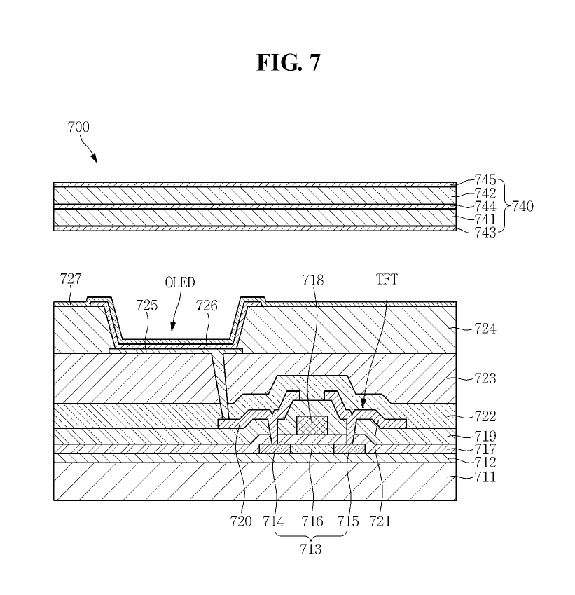

Hereinafter, referring to FIG. 7, an organic light emitting diode (“OLED”) display device manufactured using one or more exemplary embodiment of a deposition mask assembly of the invention will be described in detail.

FIG. 7 is a cross-sectional view illustrating an OLED display device 700 manufactured using one or more exemplary embodiment of a deposition mask assembly according to the invention.

Referring to FIG. 7, the OLED display device 700 includes a base substrate 711, a barrier layer 712, a semiconductor activation layer 713, a gate insulating layer 717, an insulating interlayer 719, a source electrode 720, a drain electrode 721, a passivation layer 722, a planarization layer 723, a pixel defining layer (“PDL”) 724, an OLED and an encapsulation (layer) portion 740.

The base substrate 711 may include an insulating material having flexibility. In an exemplary embodiment, for example, the base substrate 711 may include a relatively high molecular weight material such as polyimide (“PI”), polycarbonate (“PC”), polyethersulphone (“PES”), polyethylene terephthalate (“PET”), polyethylene naphthalate (“PEN”), polyarylate (“PAR”) and fiberglass reinforced plastic (“FRP”). Alternatively, the base substrate 711 may be a glass substrate. The base substrate 711 may be transparent, semitransparent or opaque.

The barrier layer 712 is disposed on the base substrate 711. The barrier layer 712 may be disposed to cover an entire portion of an upper surface of the base substrate 711. The barrier layer 712 may include an inorganic layer or an organic layer. The barrier layer 712 may have a monolayer structure or a multilayer structure. In an exemplary embodiment, for example, the barrier layer 712 may include at least one selected from: an inorganic material, such as silicon oxide (SiOx), silicon nitride (SiNx), silicon oxynitride (SiON), aluminum oxide (A10) and aluminum oxynitride (AlON), or an organic material, such as acryl, polyimide and polyester.

The barrier layer 712 serves to block oxygen and moisture, reduce or effectively prevent diffusion of moisture or undesirable materials through the base substrate 711, and provide a flat surface on the base substrate 711. A thin film transistor (“TFT”) is disposed or formed on the barrier layer 712. An exemplary embodiment of the TFT includes a TFT of a top gate structure, but exemplary embodiments are not limited thereto. An alternative exemplary embodiment of the TFT may include a TFT of a bottom gate structure or another structure.

The semiconductor activation layer 713 of the TFT is disposed on the barrier layer 712. The semiconductor activation layer 713 includes a source area 714, a drain area 715 and a channel area 716. N-type impurity ions or p-type impurity ions are doped to the semiconductor activation layer 713 such that the source area 714 and the drain area 715 are formed. An area between the source area 714 and the drain area 715 corresponds to the channel area 716 to which impurities are not doped.

The semiconductor activation layer 713 may include polysilicon or amorphous silicon. In addition, the semiconductor activation layer 713 may include an oxide semiconductor. In an exemplary embodiment, for example, the oxide semiconductor may include an oxide based on an element selected from: 4, 12, 13, and 14 group metal elements, such as zinc (Zn), indium (In), gallium (Ga), tin (Sn), cadmium (Cd), germanium (Ge), and hafnium (Hf) and combinations thereof.

The gate insulating layer 717, as a part of the TFT, is disposed on the semiconductor activation layer 713. The gate insulating layer 717 may include an inorganic layer such as silicon oxide, silicon nitride or metal oxide. The gate insulating layer 717 may have a monolayer structure or a multilayer structure. The gate insulating layer 717 may extend further from the TFT to be disposed on the base substrate 711, such as on an entirety thereof.

A gate electrode 718 of the TFT is disposed on the gate insulating layer 717. The gate electrode 718 may have a monolayer structure or a multilayer structure including, e.g., Au, Ag, Cu, Ni, Pt, Pd, Al, Mo and Cr, or an alloy such as Al:Nd and Mo:W.

The insulating interlayer 719, as a part of the TFT, is disposed on the gate electrode 718. The insulating interlayer 719 may include an insulating material such as silicon oxide or silicon nitride. In addition, the insulating interlayer 719 may include an insulating organic layer. The insulating interlayer 719 may extend further from the TFT to be disposed on the base substrate 711, such as on an entirety thereof.

The source electrode 720 and the drain electrode 721 of the TFT are disposed on the insulating interlayer 719. In an exemplary embodiment of manufacturing the OLED display device, for example, portions of the gate insulating layer 717 and the insulating interlayer 719 may be removed to define contact holes within the TFT, the source electrode 720 may be electrically connected to the source area 714 through the contact hole, and the drain electrode 721 may be electrically connected to the drain area 715 through the contact hole.

The passivation layer 722 is disposed on the source electrode 720 and the drain electrode 721. The passivation layer 722 may include an organic layer or an inorganic layer such as silicon oxide or silicon nitride.

The planarization layer 723 is disposed on the passivation layer 722. The planarization layer 723 may include an organic layer including, e.g., acryl, polyimide, and/or benzocyclobutene (“BCB”).

The OLED may be disposed or formed above the TFT. The OLED may include a first electrode 725, a second electrode 727, and an intermediate layer 726 between the first electrode 725 and the second electrode 727.

The first electrode 725 is electrically connected to one of the source electrode 720 and the drain electrode 721 of the TFT through a contact hole. Such contact hole may be defined in the passivation layer 722 and/or the planarization layer 723. The first electrode 725 corresponds to a pixel electrode.

The first electrode 725 functions as an anode of the OLED, and may include various conductive materials. The first electrode 725 may be a transparent electrode or a reflective electrode. In an exemplary embodiment, for example, in a case where the first electrode 725 is a transparent electrode, the first electrode 725 may include, e.g., ITO, IZO, ZnO, and In₂O₃. In a case where the first electrode 725 is a reflective electrode, the first electrode 725 may form a reflective layer including, e.g., Ag, Mg, Al, Pt, Pd, Au, Ni, Nd, Ir, Cr, and/or a compound thereof, and a layer including, e.g., indium tin oxide (“ITO”), indium zinc oxide (“IZO”), zinc oxide (ZnO), and/or indium oxide (In₂O₃) may be formed above the reflective layer.

The PDL 724 is disposed on the planarization layer 723 to cover an edge portion of the first electrode 725. The OLED display device includes a pixel or sub-pixel at which an image is displayed and at which light is emitted to display the image. The pixel or sub-pixel may include a light emission area at which light is generated and/or emitted, and a light non-emission area at which the light is not generated and/or emitted. In a top plan view, the PDL 724 surrounds the edge portion of the first electrode 725 to define the light emission area of each sub-pixel.

The PDL 724 may include an organic material or an inorganic material. In an exemplary embodiment, for example, the PDL 724 may include an organic material, such as polyimide, polyamide, benzocyclobutene, an acrylic resin and a phenol resin, or an inorganic material such as SiNx. The PDL 724 may have a monolayer structure and a multilayer structure.

The intermediate layer 726 is disposed on the first electrode 725. The intermediate layer 726 may be disposed in an area exposed by an etched portion of the PDL 724 which defines an aperture therein. The intermediate layer 726 may be formed by a deposition process.

The intermediate layer 726 may include a relatively low molecular weight organic material or a relatively high molecular weight organic material. The intermediate layer 726 may include an organic emissive layer (“EML”) which is used to generate and/or emit light. In addition, the intermediate layer 726 may further include at least one of a hole injection layer (“HIL”), a hole transporting layer (“HTL”), an electron transporting layer (“ETL”) and an electron injection layer (“EIL”), in addition to the organic EML. However, exemplary embodiments are not limited thereto, and the intermediate layer 726 may include various functional layers, in addition to the organic EML.

The second electrode 727 is disposed on the intermediate layer 726. The second electrode 727 corresponds to a common electrode. The common electrode may commonly correspond to more than on OLED, but the invention is not limited thereto. The second electrode 727, similar to the first electrode 725, may be a transparent electrode or a reflective electrode.

The first electrode 725 may be disposed to have a discrete shape corresponding to an aperture of each sub-pixel, such as that defined by the PDL 724. In contrast, the second electrode 727 may be disposed over an entire surface of the substrate 711. In an alternative exemplary embodiment, the second electrode 727 may have a predetermined (discrete) pattern rather than being deposited over the entire surface of the substrate 711. A position of the first electrode 725 and a position of the second electrode 727 may be exchangeable in the thickness direction of the OLED device.

In an exemplary embodiment, the first electrode 725 and the second electrode 727 are insulated from each other by the intermediate layer 726. When an electrical voltage is applied to the first electrode 725 and the second electrode 727, visible light is emitted from the intermediate layer 726 such that an image may be displayed to be recognized by a user.

The encapsulation portion 740 is disposed above the OLED. The encapsulation portion 740 protects the intermediate layer 726 and other thin films of the OLED device from external moisture or oxygen.

The encapsulation portion 740 may have a structure in which at least one organic layer and at least one inorganic layer are stacked. In an exemplary embodiment, for example, the encapsulation portion 740 may have a structure in which an organic layer 741 and 742, including, e.g., epoxy, polyimide, polyethylene terephthalate, polycarbonate, polyethylene and/or polyacrylate, and an inorganic layer 743, 744 and 745, including, e.g., silicon oxide (SiO₂), silicon nitride (SiNx), aluminum oxide (Al₂O₃), titanium oxide (TiO₂), zirconium oxide (ZrOx) and/or zinc oxide (ZnO), are stacked.

In an exemplary embodiment, the encapsulation portion 740 may have a structure that includes at least one among organic layers 741 and 742 and at least two among inorganic layers 743, 744 and 745. An uppermost layer 745 of the encapsulation portion 740 that is externally exposed may include an inorganic layer to prevent moisture permeation to the OLED.

As set forth hereinabove, in one or more exemplary embodiments, a deposition mask assembly may improve precision and uniformity of deposition by effectively reducing bending or sagging of a mask.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Various features of the above described and other embodiments can be mixed and matched in any manner, to produce further embodiments consistent with the invention.

What is claimed is:

1. A deposition mask assembly comprising:
a frame comprising:
an opening area through which a deposition material passes, and
first, second, third and fourth side portions which collectively define the opening area;
a pair of auxiliary masks on the frame, the pair of auxiliary masks being:
fixed to the first side portion and the third side portion of the frame which face each other in a first direction with respect to the opening area thereof, and
disposed respectively adjacent to the second side portion and the fourth side portion of the frame which face each other in a second direction crossing the first direction; and
a deposition divided mask spaced apart from each of the pair of auxiliary masks, the divided deposition mask fixed to the first side portion and the third side portion of the frame,
wherein in the second direction, a width of each of the pair of auxiliary masks is less than a width of the divided mask.

2. The deposition mask assembly as claimed in claim 1, wherein the pair of auxiliary masks do not overlap the second side portion and the fourth side portion of the frame which face each other in the second direction.

3. The deposition mask assembly as claimed in claim 1, wherein the width of each of the pair of auxiliary masks is in a range of about 3 millimeters to about 20 millimeters.

4. The deposition mask assembly as claimed in claim 1, wherein a thickness of each of the pair of auxiliary masks is less than a thickness of the divided mask.

5. The deposition mask assembly as claimed in claim 1, wherein in a third direction crossing each of the first and second directions, a thickness of each of the pair of auxiliary masks is in a range of about 5 micrometers to about 20 micrometers.

6. The deposition mask assembly as claimed in claim 1, wherein the pair of auxiliary masks comprise a same material as a material included in the divided mask.

7. The deposition mask assembly as claimed in claim 6, wherein the pair of auxiliary masks comprises an invar alloy.

8. The deposition mask assembly as claimed in claim 1, wherein the pair of auxiliary masks are weld-fixed to the first side portion and the third side portion.

9. The deposition mask assembly as claimed in claim 1, wherein the frame further comprises a supporting member disposed across the opening area, the supporting member overlapping the divided mask.

10. The deposition mask assembly as claimed in claim 9, wherein the supporting member and the frame are unitary.

11. The deposition mask assembly as claimed in claim 9, wherein
the divided mask comprises a deposition pattern portion through which the deposition material passes and a non-deposition portion at which the deposition material does not pass, and
the supporting member does not overlap the deposition pattern portion of the divided mask.

12. The deposition mask assembly as claimed in claim 9, wherein the supporting member is provided in plurality to overlap a same divided mask, the plurality of supporting members dividing the opening area of the frame into a plurality of opening sub-areas through which the deposition material passes.

13. The deposition mask assembly as claimed in claim 1, wherein the pair of auxiliary masks are non-deposition masks through which the deposition material does not pass.

14. The deposition mask assembly as claimed in claim 1, wherein
in the second direction,
the pair of auxiliary masks are respectively spaced apart from the second side portion and the fourth side portion of the frame, and
the divided mask is provided in plurality between the pair of auxiliary masks to be spaced apart from each other and from each of the pair of auxiliary masks, and
each divided mask is fixed to the first side portion and the third side portion of the frame.
